(19) United States
(12) Patent Application Publication
(10) Pub. No.: US 2026/0079336 A1
(43) Pub. Date: Mar. 19, 2026

(54) MEMS MIRROR, MICROMIRROR ARRAY AND ILLUMINATION SYSTEM FOR A LITHOGRAPHY SYSTEM, LITHOGRAPHY SYSTEM, AND METHOD FOR PRODUCING A LITHOGRAPHY SYSTEM

(71) Applicant: Carl Zeiss SMT GmbH, Oberkochen (DE)

(72) Inventors: Stefan WALZ, Schwaebisch Gmuend (DE); Oliver HERBST, Aalen (DE); Markus HOLZ, Aalen (DE); Steffen VAAS, Ellwangen (DE)

(21) Appl. No.: 19/344,604

(22) Filed: Sep. 30, 2025

Related U.S. Application Data
(63) Continuation of application No. PCT/EP2024/059808, filed on Apr. 11, 2024.

(30) Foreign Application Priority Data
Apr. 13, 2023 (DE) 10 2023 203 337.2

(51) Int. Cl. G02B 26/08; G03F 7/00

(52) U.S. Cl. CPC G02B 26/0841; G03F 7/70141; G03F 7/702

(57) ABSTRACT

A MEMS mirror for a lithography system, comprising: a mirror plate which can be displaced about a tilt angle; a carrier plate for carrying the mirror plate; a base plate; a solid-body joint, coupling the base plate and the carrier plate, for tilting the mirror plate; and a capacitive sensor having a number of electrodes for detecting the tilt angle of the mirror plate. An electrically conductive shield plate for reducing a capacitive coupling between the mirror plate and the electrodes of the capacitive sensor is arranged under the mirror plate.

### CROSS-REFERENCE TO RELATED APPLICATIONS

The present application is a continuation of, and claims benefit under 35 USC 120 to, international application No. PCT/EP2024/059808, filed Apr. 11, 2024, which claims benefit under 35 USC 119 of German Application No. 10 2023 203 337.2, filed Apr. 13, 2023. The entire disclosure of each of these applications is incorporated by reference herein.

### FIELD

The present disclosure relates to a MEMS mirror for a lithography apparatus, a micromirror array for a lithography apparatus, an illumination system for a lithography apparatus, a lithography apparatus and a method for producing a lithography apparatus.

### BACKGROUND

Microlithography is used to produce microstructured structural elements, for example integrated circuits. The microlithography process is performed using a lithography apparatus that comprises an illumination system and a projection system. The image of a mask (reticle) illuminated via the illumination system is projected here via the projection system onto a substrate, for example a silicon wafer, which is coated with a light-sensitive layer (photoresist) and is arranged in the image plane of the projection system, in order to transfer the mask structure to the light-sensitive coating of the substrate.

Driven by a general desire for ever smaller structures in the production of integrated circuits, EUV lithography apparatuses that use light at a wavelength in the range from 0.1 nm to 30 nm, such as 13.5 nm, are currently under development. Since most materials absorb light at this wavelength, such EUV lithography apparatuses typically use reflective optical units, i.e. mirrors, instead of refractive optical units, i.e. lens elements, as used previously.

The use of what are referred to as MEMS mirrors in an illumination system of a lithography apparatus is known. “MEMS” stands for “microelectromechanical system”. Such MEMS mirrors comprise what is known as a micromirror (also referred to as mirror plate) and an actuator. The actuator allows the alignment of the micromirror to be changed. During operation of the lithography apparatus, radiation (also referred to as operating light, for example EUV light) is incident on the surface of the micromirror and is reflected there. Changing the alignment of the micromirror makes it possible to influence the path taken by the EUV light through the illumination system. Such MEMS mirrors are generally manufactured on a substrate in integrated fashion. Such systems can involve only little installation space. However, there are also often considerable limitations on the installation space for electronic components in a region behind the MEMS mirrors, i.e. on the side facing away from the operating light.

The micromirrors may be e.g. secured to a carrier plate and be configured to be at least partially manipulable or tiltable in order to allow a movement of a respective mirror in up to six degrees of freedom and hence allow a highly accurate positioning of the mirrors in relation to one another, for example in the pm range. This can allows change in the optical properties that occur for instance during the operation of the lithography apparatus, e.g. as a result of thermal influences, to be corrected.

For the purposes of displacing the micromirrors, for example in the six degrees of freedom, actuators that are actuated by way of a control loop are assigned to the micromirrors. A device for monitoring the tilt angle of a respective mirror is provided as part of the control loop.

For example, WO 2009/100856 A1 discloses a facet mirror that is for a projection exposure apparatus of a lithography apparatus and comprises a multiplicity of individually displaceable individual mirrors. To ensure the optical quality of a projection exposure apparatus, it is often desirable to implement very precise positioning of the displaceable individual mirrors. Document DE 10 2013 209 442 A1 describes that the field facet mirror may take the form of a microelectromechanical system (MEMS).

The photons from the EUV radiation source in the lithography apparatus may trigger the emission of electrons from the mirror surfaces of the MEMS mirrors as a result of the photoelectric effect. This may bring about temporally and spatially varying current flows over the MEMS mirrors of the field facet mirror. These temporally and spatially varying current flows over the MEMS mirrors may significantly disturb the monitoring of the tilt angle of the respective mirror.

### SUMMARY

The present disclosure seeks to develop an improved MEMS mirror for a lithography apparatus.

In a first aspect, the disclosure provides a MEMS mirror for a lithography apparatus. The MEMS mirror has a mirror plate that can be displaced through a tilt angle, a carrier plate for carrying the mirror plate, a base plate, a flexure that couples the base plate and the carrier plate in order to tilt the mirror plate and a capacitive sensor having a number of electrodes for detecting the tilt angle of the mirror plate. In this case, an electrically conductive shielding plate is arranged under the mirror plate in order to reduce a capacitive coupling between the mirror plate and the electrodes of the capacitive sensor.

The electrically conductive shielding plate arranged under the mirror plate can help reduce the capacitive coupling between the mirror plate and the electrodes of the capacitive sensor. Hence, the effects of the disturbances caused by the electrons dislodged by way of the radiation of the radiation source on the mirror plate, on the capacitive sensor and hence on the detection of the tilt angle of the mirror plate performed by the capacitive sensor can be significantly reduced. This reduction in disturbance can help allow the position of the mirror to be determined much more precisely. A more precise determination of the position of the mirror can significantly improve the control loop for the actuation of the actuators (also referred to as control units) of the micromirrors.

The lithography apparatus or projection exposure apparatus may be an EUV lithography apparatus. EUV stands for “extreme ultraviolet” and denotes a wavelength of the operating light between 0.1 nm and 30 nm. The lithography apparatus or projection exposure apparatus may also be a DUV lithography apparatus. DUV stands for “deep ultraviolet” and denotes a wavelength of the operating light of between 30 nm and 250 nm. The guided radiation may be EUV or DUV light.

According to an embodiment, the electrically conductive shielding plate is arranged directly under the carrier plate that carries the mirror plate. The immediate arrangement near the mirror plate can help optimize the capacitive decoupling between the mirror plate and the electrodes of the capacitive sensor.

According to an embodiment, the shielding plate is grounded separately. The shielding plate can be connected to ground via a separate grounding line provided for grounding the shielding plate. The dedicated grounding line for the shielding plate can help reliably ensure that the electrons dislodged by the radiation of the radiation source can reliably flow away, for example without causing significant disturbances.

According to an embodiment, the capacitive sensor has an upper electrode arranged in the direction of the mirror plate and a lower electrode arranged in the direction of the base plate for measuring the tilt angle of the mirror plate of the MEMS mirror.

In accordance with an embodiment, the electrodes of the capacitive sensor are in the shape of a comb and are arranged in intermeshed fashion.

According to an embodiment, the comb-shaped electrodes of the capacitive sensor each have a cutout through which the flexure that couples the carrier plate and the base plate is guided. For example, the flexure is guided through the two cutouts of the comb-shaped electrodes of the capacitive sensor and hence connects the carrier plate and the base plate of the MEMS mirror. The mirror plate of the MEMS mirror can be tilted through the tilt angle by way of the flexure.

According to a second aspect, the disclosure provides a micromirror array for a lithography apparatus. The micromirror array comprises a plurality of MEMS mirrors, wherein each respective MEMS mirror is formed according to the first aspect or according to one of the embodiments of the first aspect.

According to a third aspect, the disclosure provides an illumination system for a lithography apparatus. The illumination system comprises at least one micromirror array according to the second aspect.

According to a fourth aspect, the disclosure provides a lithography apparatus, comprising:
a radiation source for generating radiation having a specific repetition frequency,
a MEMS mirror that can be displaced through a tilt angle according to the first aspect or according to one of the embodiments of the first aspect for guiding the radiation within the lithography apparatus,
a detection device that is configured to detect the tilt angle of the mirror plate of the MEMS mirror via a measurement signal received via the capacitive sensor of the MEMS mirror, in order to provide a time-discrete tilt angle signal, and
an evaluation unit that is configured to determine the position of the MEMS mirror via the time-discrete tilt angle signal.

According to an embodiment, the MEMS mirror can be displaced about at least two tilt axes, such as about two mutually orthogonal tilt axes. In this context, at least two control units for actuating the mirror plate can be provided per tilt axis in order to displace the mirror plate.

According to an embodiment, at least two sensor units for acquiring a respective measurement signal from the capacitive sensor of the MEMS mirror are provided per tilt axis. By using the shielding plate, the negative disturbances on the sensor units for measuring the tilt angle that are caused by electrons dislodged by incident radiation, as discussed above, are considerably reduced.

According to an embodiment, the mirror plate is connected to ground via a first resistor, the shielding plate is connected to ground via a second resistor, and the upper electrode of the capacitive sensor is connected to ground via a third resistor.

According to an embodiment, the lithography apparatus comprises a vacuum housing in which the radiation source, the MEMS mirror, the detection device and the evaluation unit are arranged. For example, the vacuum housing is designed for a pressure of 1013.25 hPa to 10⁻³ hPa, such as 10⁻³ to 10⁻⁸ hPa, for example 10⁻⁸ to 10⁻¹¹ hPa in its interior.

According to an embodiment, the lithography apparatus comprises a controller arranged externally to the vacuum housing and serving to control the radiation source via a control signal.

According to an embodiment, the MEMS mirror, the detection device and the evaluation unit are arranged in an illumination system of the lithography apparatus.

According to an embodiment, the radiation source is an EUV radiation source.

In embodiments, the mirror plate is coupled to ground by an electrical connection, for example with a dedicated electrical connection, for the low-resistance grounding of the mirror plate. This reduces the resistance to ground, whereby the capacitive coupling between the mirror plate and the electrodes of the capacitive sensor can be reduced further. In embodiments, it is also proposed to reduce the coupling capacity between the mirror plate and the electrodes of the capacitive sensor in order to reduce the coupling of electrons dislodged from the mirror plate into the electrodes of the capacitive sensor.

The embodiments described for the proposed MEMS mirror according to the first aspect apply accordingly to the proposed lithography apparatus according to the second aspect. Furthermore, the definitions and explanations in relation to the MEMS mirror also apply correspondingly to the proposed lithography apparatus.

The respective unit, for example the control unit, may be implemented in hardware and/or software. In a hardware implementation, the unit may be designed as a device or as a part of a device, for example as a computer or as a microprocessor or as part of the controller. In a software implementation, the unit may be designed as a computer program product, as a function, as a routine, as part of a program code or as an executable object.

According to a fifth aspect, the disclosure provides a method for producing a MEMS mirror for a lithography apparatus, which includes the following steps:
providing a carrier plate,
arranging on the carrier plate a mirror plate that can be displaced through a tilt angle,
providing a base plate,
coupling the base plate and the carrier plate via a flexure in order to tilt the mirror plate, and
arranging a capacitive sensor having a number of electrodes for detecting the tilt angle of the mirror plate between the base plate and the carrier plate,
wherein an electrically conductive shielding plate is arranged under the mirror plate in order to reduce a capacitive coupling between the mirror plate and the electrodes of the capacitive sensor.

According to an embodiment, the electrodes of the capacitive sensor are of comb-shaped form and arranged in meshed fashion, wherein the comb-shaped electrodes of the capacitive sensor each have a cutout through which the flexure that couples the carrier plate and the base plate is guided.

The embodiments described for the proposed MEMS mirror according to the first aspect apply accordingly to the proposed method according to the fifth aspect. Furthermore, the definitions and explanations given in relation to the MEMS mirror also apply accordingly to the proposed method.

“A(n)” in the present case should not necessarily be understood as restrictive to exactly one element. Instead, there may also be provision for multiple elements, for example two, three or more. Any other numeral used here should also not be understood as a restriction to exactly the stated number of elements. Rather, unless indicated otherwise, numerical variances upwards and downwards are possible.

Further possible implementations of the disclosure also comprise combinations not explicitly mentioned of features or embodiments which were described above or will be described in the following text in relation to the exemplary embodiments. A person skilled in the art will also add individual aspects as improvements or supplementations to the respective basic form of the disclosure.

Further features, configurations and aspects of the disclosure are the subject of the dependent claims and of the exemplary embodiments of the disclosure that are described hereinafter. The disclosure is elucidated in detail hereinafter on the basis of certain embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic view of an embodiment of an aspect of the lithography apparatus; and

FIG. 3 shows an embodiment of a method for producing a MEMS mirror for a lithography apparatus.

### DETAILED DESCRIPTION

In the figures, identical or functionally identical elements have been provided with the same reference signs, unless indicated otherwise. Further, it should be noted that the representations in the figures are not necessarily true to scale.

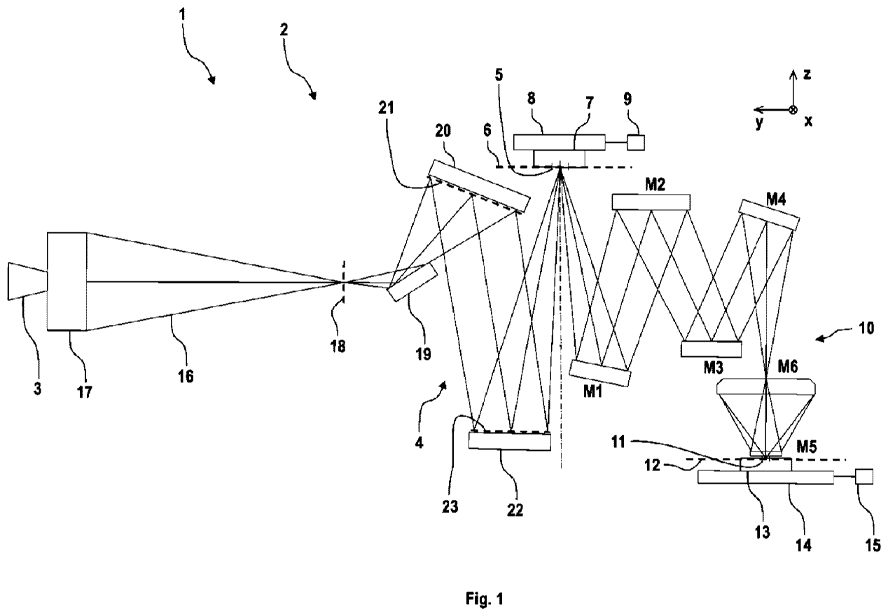

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, by way of elucidation, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optics unit 10. The projection optics unit 10 serves to image the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement, firstly, of the reticle 7 by way of the reticle displacement drive 9 and, secondly, of the wafer 13 by way of the wafer displacement drive 15 can be implemented so as to be in sync with one another.

The light source 3 is an EUV radiation source. The light source 3 emits EUV radiation 16, which is also referred to below as used radiation, illumination radiation or illumination light. The used radiation 16 has for example a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optics unit 4.

The illumination optics unit 4 comprises a deflection mirror 19 and, arranged downstream thereof in the beam path, a first facet mirror 20. The deflection mirror 19 may be a planar deflection mirror or alternatively a mirror with a beam-influencing effect going beyond the pure deflection effect. In an alternative to that or in addition, the deflection mirror 19 may take the form of a spectral filter that separates a used light wavelength of the illumination radiation 16 from extraneous light of a wavelength differing therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may take the form of macroscopic facets, for example rectangular facets or facets with an arc-shaped or part-circular edge contour. The first facets 21 may take the form of planar facets or, alternatively, convexly or concavely curved facets.

As is known for example from DE 10 2008 009 600 A1, the first facets 21 themselves may also be composed in each case of a multiplicity of individual mirrors, for example a multiplicity of micromirrors. The first facet mirror 20 may be in the form of a microelectromechanical system (MEMS system) for example. For details, reference is made to DE 10 2008 009 600 A1.

The illumination radiation 16 travels horizontally, i.e. in the y-direction y, between the collector 17 and the deflection mirror 19.

In the beam path of the illumination optics unit 4, a second facet mirror 22 is disposed downstream of the first facet mirror 20. Should the second facet mirror 22 be arranged in a pupil plane of the illumination optics unit 4, it is also referred to as a pupil facet mirror. The second facet mirror 22 may also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may also be macroscopic facets, which may for example have a round, rectangular or hexagonal boundary, or may alternatively be facets composed of micromirrors. In this regard, reference is also made to DE 10 2008 009 600 A1.

The second facets 23 may have planar or, alternatively, convexly or concavely curved reflection surfaces.

The illumination optics unit 4 thus forms a doubly faceted system. This fundamental principle is also referred to as a fly's eye integrator.

It may be desirable to arrange the second facet mirror 22 not exactly in a plane that is optically conjugate to a pupil plane of the projection optics unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In an embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may comprise exactly one mirror, or alternatively two or more mirrors, which are arranged one behind the other in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In an embodiment of the illumination optics unit 4, the deflection mirror 19 may also be omitted, and so the illumination optics unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is often only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are also possible. The projection optics unit 10 is a doubly obscured optics unit. The penultimate mirror M5 and the last mirror M6 each have a passage opening for the illumination radiation 16. The projection optics unit 10 has an image-side numerical aperture that is greater than 0.5 and may also be greater than 0.6 and for example may be 0.7 or 0.75.

Reflection surfaces of the mirrors Mi may take the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image shift in the y-direction y between a y-coordinate of a center of the object field 5 and a y-coordinate of the center of the image field 11. This object-image shift in the y-direction y may be of approximately the same magnitude as a z-distance between the object plane 6 and the image plane 12.

The projection optics unit 10 may for example have an anamorphic form. For example, it has different imaging scales βx, βy in the x- and y-directions x, y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are also possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optics unit 10. Examples of projection optics units with different numbers of such intermediate images in the x-direction x and y-direction y are known from US 2018/0074303 A1.

In each case one of the second facets 23 is assigned to exactly one of the first facets 21 in order to form a respective illumination channel for illuminating the object field 5. This may for example produce illumination according to the Köhler principle. The far field is decomposed into a multiplicity of object fields 5 using the first facets 21. The first facets 21 generate a plurality of images of the intermediate focus on the second facets 23 respectively assigned to them.

By way of an assigned second facet 23, the first facets 21 are each imaged onto the reticle 7 and overlaid on one another for the purpose of illuminating the object field 5. The illumination of the object field 5 is for example of maximum homogeneity. It can have a uniformity error of less than 2%. Field uniformity can be achieved by overlaying different illumination channels.

An arrangement of the second facets 23 may geometrically define the illumination of the entrance pupil of the projection optics unit 10. The intensity distribution in the entrance pupil of the projection optics unit 10 may be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optics unit 4 which are illuminated in a defined manner may be achieved by a redistribution of the illumination channels.

Further aspects and details of the illumination of the object field 5 and, for example, of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of imaging by the projection optics unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optics unit 10 has different positions of the entrance pupil for the tangential beam path and for the sagittal beam path. In this case, an imaging element, for example an optical structural element of the transfer optics unit, should be provided between the second facet mirror 22 and the reticle 7. This optical element can be used to take into account the different position of the tangential entrance pupil and the sagittal entrance pupil.

In the arrangement of the components of the illumination optics unit 4 shown in FIG. 1, the second facet mirror 22 is arranged in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

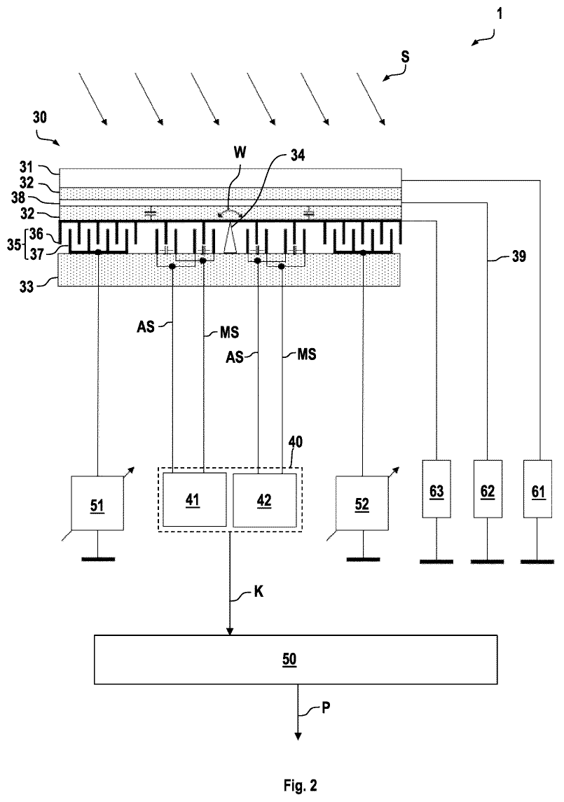

FIG. 2 shows a schematic view of an embodiment of one aspect of a lithography apparatus or projection exposure apparatus 1, as shown in FIG. 1, for example.

In this case, FIG. 2 shows the radiation S that is generated by the radiation source 3 in the lithography apparatus 1 according to FIG. 1 and has a specific repetition frequency. Furthermore, FIG. 2 shows a MEMS mirror 30 that can be displaced through a tilt angle W for guiding the radiation S within the lithography apparatus 1. The MEMS mirror 30 may for example be part of one of the mirrors 20, 22, M1-M6 in the lithography apparatus 1 of FIG. 1.

The MEMS mirror 30 has a mirror plate 31 that can be displaced through the tilt angle W, a carrier plate 32 for carrying the mirror plate 31, a base plate 33, a flexure 34 that couples the carrier plate 32 and the base plate 33 and a capacitive sensor 35 having a number of electrodes 36, 37 arranged between the carrier plate 32 and the base plate 33.

An electrically conductive shielding plate 38 is arranged under the carrier plate 32 that carries the mirror plate 31. The electrically conductive shielding plate 38 is configured to reduce a capacitive coupling between the mirror plate 31 and the electrodes 36, 37 of the capacitive sensor 35.

The electrically conductive shielding plate 38 can be arranged directly under the carrier plate 32 that carries the mirror plate 31. For example, the electrically conductive shielding plate 38 is arranged between the carrier plate 32 that carries the mirror plate 31 and a further carrier plate 32.

As also illustrated in FIG. 2, the capacitive sensor 35 has an upper electrode 36 arranged in the direction of the mirror plate 31 and a lower electrode 37 arranged in the direction of the base plate 33 for measuring the tilt angle W of the mirror plate 31 of the MEMS mirror 30. In the example of FIG. 2, the upper electrode 36 is arranged on the further carrier plate 32, whereas the lower electrode 37 is arranged on the base plate 33. The electrodes 36, 37 of the capacitive sensor 35 are of comb-shaped form and arranged in meshed fashion. The comb-shaped electrodes 36, 37 of the capacitive sensor 35 each have a respective cutout through which the flexure 34 that couples the carrier plate 32 and the base plate 33 is guided.

The mirror plate 31 is connected to ground via a first resistor 61. As also shown in FIG. 2, the shielding plate 38 is grounded separately. To this end, the shielding plate 38 is connected to ground via a second resistor 62 via a separate grounding line 39 provided for grounding the shielding plate 38. Moreover, the upper electrode 36 of the capacitive sensor 35 is connected to ground via a third resistor 63.

The MEMS mirror 30 is displaceable for example about two tilt axes, such as about two tilt axes that are orthogonal to each other. For the purpose of displacing the mirror plate 31, two control units 51, 52 for actuating the mirror plate 31 are provided per tilt axis.

In this context, the sectional view of the MEMS mirror 30 in FIG. 2 shows one tilt axis. The detection device 40 of FIG. 2 comprises for example the aforementioned capacitive sensor 35 (or is coupled therewith) and two sensor units 41 and 42 per tilt axis. As explained above, the capacitive sensor 35 is configured to measure the tilt angle W of the mirror plate 31 of the MEMS mirror 30. The respective sensor unit 41, 42 is configured to excite the capacitive sensor 35 via an excitation signal AS and receive the measurement signal MS in response thereto. Hence, the detection device 40 is configured to detect the tilt angle W of the MEMS mirror 30 via a measurement signal MS having a measurement signal frequency, in order to provide a time-discrete tilt angle signal K. The measurement signal frequency can be greater than the repetition frequency. For example, the measurement signal frequency is greater than the repetition frequency by at least a factor of 2.

The time-discrete tilt angle signal K provided by the detection device 40 is supplied to an evaluation unit 50. The evaluation unit 50 is configured to determine the position P of the MEMS mirror 30 via the time-discrete tilt angle signal K.

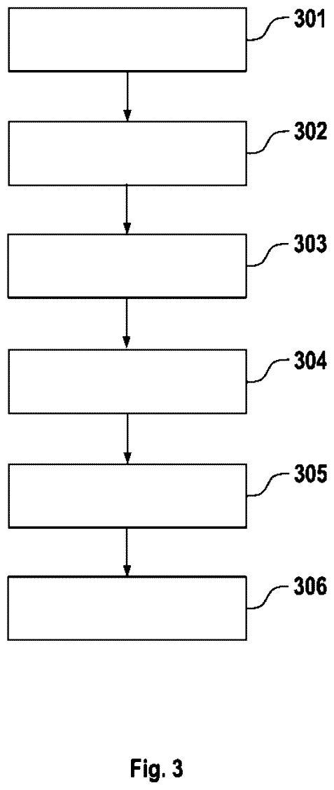

FIG. 3 shows an embodiment of a method for producing a MEMS mirror 30 for a lithography apparatus 1. An example of a lithography apparatus 1 is explained with reference to FIG. 1. An example of a MEMS mirror 30 is discussed with reference to FIG. 2.

The method in FIG. 3 comprises steps 301 to 306. The sequence of steps 301 to 306 does not necessarily correspond to the chronological sequence during the production of MEMS mirror 30.

In step 301, a carrier plate 32 is provided. In step 302, a mirror plate 31 that can be displaced through a tilt angle W is arranged on the carrier plate 32. In step 303, a base plate 33 is provided. In step 304, the base plate 33 and the carrier plate 31 are coupled (directly or indirectly) via a flexure 34 in order to tilt the mirror plate 31.

In step 305, a capacitive sensor 35 having a number of electrodes 36, 37 for detecting the tilt angle W of the mirror plate 31 is arranged between the base plate 33 and the carrier plate 32. According to step 306, an electrically conductive shielding plate 38 is arranged under the mirror plate 31 in order to reduce a capacitive coupling between the mirror plate 31 and the electrodes 36, 37 of the capacitive sensor 35.

Although the present disclosure has been described with reference to exemplary embodiments, it is modifiable in a variety of ways.

### LIST OF REFERENCE SIGNS

1 Projection exposure apparatus
2 Illumination system
3 Radiation source
4 illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
30 Mirror
31 Mirror plate
32 Carrier plate
33 Base plate
34 Flexure
35 Capacitive sensor
36 Upper comb-shaped electrode
37 Lower comb-shaped electrode
38 Shielding plate
39 Grounding line
40 Detection device
41 Sensor unit
42 Sensor unit
51 Control unit
52 Control unit
61 Resistor
62 Resistor
63 Resistor
301-306 Method steps
AS Excitation signal
K Tilt angle signal
M1 Mirror
M2 Mirror
M3 Mirror
M4 Mirror
M5 Mirror
M6 Mirror
MS Measurement signal
P Position of the mirror
S Radiation
W Tilt angle

What is claimed is:

1. A MEMS mirror, comprising:
a mirror plate displaceable through a tilt angle;
a carrier plate supporting the mirror plate;
a base plate;
a flexure coupling the base plate and the carrier plate to tilt the mirror plate;
a capacitive sensor comprising a number of electrodes configured to detect the tilt angle of the mirror plate; and
an electrically conductive shielding plate configured to reduce a capacitive coupling between the mirror plate and the electrodes of the capacitive sensor.

2. The MEMS mirror of claim 1, wherein the electrically conductive shielding plate is under the mirror plate.

3. The MEMS mirror of claim 1, wherein the electrically conductive shielding plate is directly under the carrier plate.

4. The MEMS mirror of claim 1, wherein the carrier plate is between the mirror plate and the electrically conductive shielding plate.

5. The MEMS mirror of claim 1, wherein the electrically conductive shielding plate is between the mirror plate and the capacitive sensor.

6. The MEMS mirror of claim 1, wherein the shielding plate is grounded separately.

7. The MEMS mirror of claim 6, wherein the shielding plate is connected to ground via a separate grounding line.

8. The MEMS mirror of claim 1, wherein the number of electrodes comprises first and second electrodes, and the first electrode is between the mirror plate and the second electrode.

9. The MEMS mirror of claim 8, wherein each of the first and second electrodes is comb-shaped form, and the first and second electrodes are enmeshed with each other.

10. The MEMS mirror of claim 9, wherein each of the first and second electrodes has a cutout through which the flexure is disposed.

11. A mirror array, comprising:
a plurality of MEMS mirrors according to claim 1,
wherein the mirror array is a micromirror array.

12. A system, comprising:
a micromirror array comprising a plurality of MEMS mirrors according to claim 1,
wherein the system is a lithography illumination system.

13. An apparatus, comprising:
a radiation source configured to generate radiation;
a MEMS mirror according to claim 1;
a detection device configured to detect the tilt angle of the mirror plate of the MEMS mirror via a measurement signal received via the capacitive sensor to provide a time-discrete tilt angle signal; and
an evaluation unit configured to determine a position of the MEMS mirror via the time-discrete tilt angle signal,
wherein the apparatus is a lithography apparatus.

14. The apparatus of claim 13, wherein:
the MEMS mirror is displaceable about two tilt axes; and
the apparatus further comprises, per tilt axis, at least two control units configured to actuate the mirror plate to displace the mirror plate.

15. The apparatus of claim 14, further comprising, per tilt axis, at least two sensor units configured to acquire a respective measurement signal from the capacitive sensor of the MEMS mirror.

16. The apparatus of claim 13, wherein the MEMS mirror is displaceable about two mutually orthogonal tilt axes, and the apparatus comprises at least two control units configured to actuate the mirror plate per tilt axis to displace the mirror plate.

17. The apparatus of claim 13, wherein the mirror plate is connected to ground via a first resistor, the shielding plate is connected to ground via a second resistor, and a first electrode of the capacitive sensor is connected to ground via a third resistor.

18. A method, comprising:
supporting a mirror plate with a carrier plate, the mirror plate being displaceable through a tilt angle;
including a capacitive sensor between the base plate and a carrier plate, the capacitive sensor comprising a number of electrodes configured to detect the tilt angle of the mirror plate;
coupling the base plate and the carrier plate via a flexure configured to tilt the mirror plate; and
including an electrically conductive shielding plate configured to reduce a capacitive coupling between the mirror plate and the electrodes of the capacitive sensor, thereby providing a MEMS mirror.

19. The method of claim 18, wherein the electrically conductive shielding plate is under the mirror plate.

20. The method of claim 18, wherein:
the electrodes comprising first and second electrodes;
each of the first and second electrodes is comb-shaped form;
the first and second electrodes are enmeshed with each other;
each of the first and electrodes has a cutout through which the flexure is disposed.
